(19) United States
(12) Patent Application Publication
(10) Pub. No.: US 2013/0062744 A1
(43) Pub. Date: Mar. 14, 2013

(54) POWER MODULE PACKAGE

(71) Applicants: Kwang Soo Kim, Gyunggi-do (KR); Jung Eun Kang, Gyunggi-do (KR); Young Ki Lee, Gyunggi-do (KR)

(72) Inventors: Kwang Soo Kim, Gyunggi-do (KR); Jung Eun Kang, Gyunggi-do (KR); Young Ki Lee, Gyunggi-do (KR)

(73) Assignee: SAMSUNG ELECTRO-MECHANICS CO., LTD., Gyunggi-do (KR)

(21) Appl. No.: 13/316,121

(22) Filed: Dec. 9, 2011

(30) Foreign Application Priority Data
Sep. 14, 2011 (KR) 1020110092594

(51) Int. Cl. H01L 23/495

(52) U.S. Cl. 257/675; 257/E23.031

(57) ABSTRACT

Disclosed herein is a power module package, including: a first substrate having one surface and the other surface; first vias formed to penetrate from one surface of the first substrate to the other surface thereof; a metal layer formed on one surface of the first substrate; semiconductor devices formed on the metal layer; and a metal plate formed on the other surface of the first substrate.

### CROSS REFERENCE TO RELATED APPLICATION

This application claims the benefit of Korean Patent Application No. 10-2011-0092594, filed on Sep. 14, 2011, entitled “Power Module Package”, which is hereby incorporated by reference in its entirety into this application.

### BACKGROUND OF THE INVENTION

1. Technical Field

The present invention relates to a power module package.

2. Description of the Related Art

With increase in energy consumption around the world, an efficient use of restricted energy has been attracting much attention. Therefore, a use of an inverter adopting an intelligent power module (IPM) for efficiently converting energy in the existing home and industrial appliances has accelerated.

With the increase in the use of the power module, a demand in a market for high-integration, high-capacity, and small-sized products has increased. Thus, the high integration of the power module has caused heat generation in electronic components and deterioration in performance of the entire module.

Therefore, a demand exists for a high integration/high heat radiation package structure capable of solving the heat generation as described above, in order to improve efficiency of the power module and secure high reliability thereof.

### SUMMARY OF THE INVENTION

The present invention has been made in an effort to provide a power module package with improved heat radiation characteristics.

According to a first preferred embodiment of the present invention, there is provided a power module package, including: a first substrate having one surface and the other surface; first vias formed to penetrate from one surface of the first substrate to the other surface thereof; a metal layer formed on one surface of the first substrate; semiconductor devices formed on the metal layer; and a metal plate formed on the other surface of the first substrate.

The semiconductor devices may include a power device and control devices, the power device having a heat sink formed thereon.

The semiconductor devices may include a power device and control devices, and the first vias include a heat radiation via and a signal via, the power device being formed on the metal layer and being formed to correspond to a region on which the heat radiation via is formed.

The first vias may include a heat radiation via and a signal via, and the metal plate is connected to the heat radiation via.

The semiconductor devices may include a power device and control devices, and the first vias may include a heat radiation via and a signal via, the control devices being formed on the metal layer and being formed to correspond to a region on which the signal via is formed.

The semiconductor devices may include a power device and control devices, the power device and the control devices each being formed as a package type.

The power module package may further include a lead frame electrically interconnecting a package type of semiconductor device and the metal layer, in the case of the package type of semiconductor device.

The power module may further include a wire electrically interconnecting the semiconductor device and the metal layer.

The power module package may further include a second substrate formed on the other surface of the first substrate and connected to the first substrate through the metal plate.

The power module package may further include second vias formed to penetrate from one surface of the second substrate to the other surface thereof, wherein the second via is connected to the metal plate.

According to a second preferred embodiment of the present invention, there is provided a power module package, including: a first substrate having one surface and the other surface; vias formed to penetrate from one surface of the first substrate to the other surface thereof; a metal layer formed on one surface of the first substrate; and semiconductor devices formed on the metal layer.

The semiconductor devices may include a power device and control devices, the power device having a heat sink formed thereon.

The semiconductor devices may include a power device and control devices, and the vias may include a heat radiation via and a signal via, the power device being formed on the metal layer and being formed to correspond to a region on which the heat radiation via is formed.

The semiconductor devices may include a power device and control devices, and the vias may include a heat radiation via and a signal via, the control devices being formed on the metal layer and being formed to correspond to a region on which the signal via is formed.

The semiconductor devices may include a power device and control devices, the power device and the control devices each being formed as a package type.

The power module package may further include a lead frame electrically interconnecting a package type of semiconductor device and the metal layer, in the case of the package type of semiconductor device.

The power module package may further include a wire electrically interconnecting the semiconductor device and the metal layer.

The power module package may further include a second substrate formed on the other surface of the first substrate.

### BRIEF DESCRIPTION OF THE DRAWINGS

FIG. 1 is a cross-sectional view showing a configuration of a power module package according to a first preferred embodiment of the present invention;

FIG. 2 is a cross-sectional view showing a configuration of a power module package according to a second preferred embodiment of the present invention; to FIG. 3 is a cross-sectional view showing one example of a first substrate according to the present invention;

FIG. 4 is a cross-sectional view showing the other example of the first substrate according to the present invention; and

FIGS. 5 and 6 are plan views explaining examples in which a power module package is disposed according to the preferred embodiment of the present invention.

### DESCRIPTION OF THE PREFERRED EMBODIMENTS

Various features and advantages of the present invention will be more obvious from the following description with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, a detailed description thereof will be omitted. In the description, the terms “first”, “second”, and so on are used to distinguish one element from another element, and the elements are not defined by the above terms.

Hereinafter, preferred embodiments of the present invention will be described in detail with reference to the accompanying drawings.

### Power Module Package—First Preferred Embodiment

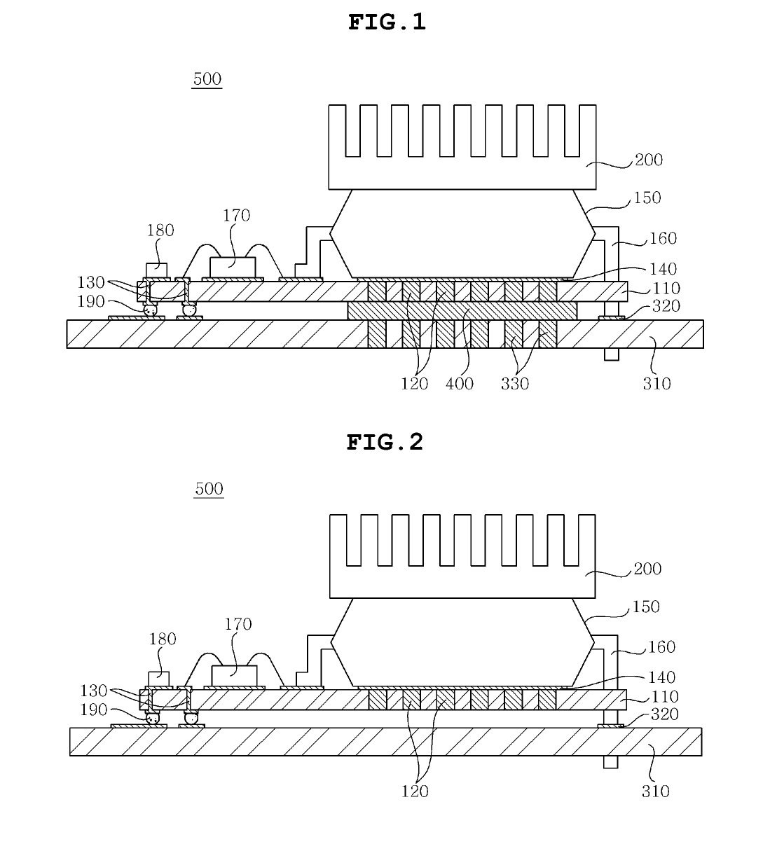

FIG. 1 is a cross-sectional view showing a configuration of a power module package according to a first preferred embodiment of the present invention.

Referring to FIG. 1, a power module package 500 may be configured to include a first substrate 110 having one surface and the other surface, first vias 120 and 130 formed to penetrate from one surface of the first substrate 110 to the other surface thereof, a metal plate 400 formed on the other surface of the first substrate 110, a metal layer 140 formed on one surface of the first substrate 110, and semiconductor devices 150, 170, and 180 formed on the metal layer 140.

Here, the semiconductor device may include a power device 150 and control devices 170 and 180.

In this configuration, the power device 150 and the control device 180 may also each be formed as a package type, as shown in FIGS. 1, 3 and 4.

For example, it will be defined that the power device 150 refers to a device having a large heat generation amount such as an insulated gate bipolar transistor (IGBT), diode, or the like, and the control devices 170 and 180 refer to a device having a smaller heat generation amount than the power device, such as a control integrated circuit (IC), a passive device, or the like.

In addition, the first vias 120 and 130 may include a heat radiation via 120 and a signal via 130.

Furthermore, a heat sink 200 may be formed on the power device 150.

In this configuration, the power device 150 having a larger heat generation amount than the control devices 170 and 180 is connected to the heat sink 200 and the heat radiation via 120, such that heat generated from the power device 150 can be effectively radiated.

In addition, due to effective heat radiation of the power device 150, operational reliability of the entire power module package 500 including the control devices 170 and 180 can also be improved.

In addition, the power device 150 may be formed on the metal layer 140 and be formed to correspond to a region on which the heat radiation vias 120 are formed.

In other words, the power device 150 and the heat radiation vias 120 are formed to be adjacent to each other, such that the heat radiation vias 120 may rapidly transfer the heat generated from the power device 150 to a lower portion of the power module package 500.

In addition, the control devices 170 and 180 may be formed on the metal layer 140 and be formed to correspond to a region on which the signal vias 130 are formed.

That is, as shown in FIG. 1, the control devices 170 and 180 formed on the metal layer 140 are connected to external connection terminals 190 through the signal vias 130 to thereby be electrically connected to a second substrate 310. In this case, the semiconductor device may also be connected to the signal vias 130 through wires, such as the control device 170.

FIG. 1 shows a case in which the first substrate 110 and the second substrate 310 are connected to each other in a ball grid array (BGA) scheme, but the present invention is not limited thereto and the first substrate 110 and the second substrate 310 may also be connected to each other in a land grid array (LGA) scheme, or the like.

As shown in FIGS. 1, 3 and 4, in the case of a package type of the semiconductor devices 150 and 171, the power module package 500 may further include a lead frame 160 electrically interconnecting the package type of semiconductor devices and the metal layer.

As shown in FIG. 1, the power module package 500 may further include a wire electrically interconnecting the semiconductor device 170 and the metal layer 140.

In addition, the metal plate 400 may be formed to be connected to the heat radiation vias 120.

In addition, the power module package 500 may further include a second substrate 310 formed on the other surface of the first substrate 110 and connected to the first substrate 110 through the metal plate 400.

Here, the metal plate 400 is provided between the first substrate 110 and the second substrate 310 to thereby serve to support the first substrate 310 relatively receiving pressure due to the power device 150 or the like, as compared to the second substrate 310, horizontally and vertically transfer the heat transferred through the heat radiation vias 120, and electrically connect between the first substrate 110 and the second substrate 310.

Since the metal plate 400 secondarily transfers the heat primarily transferred through the heat radiation vias 120, it rapidly radiates the heat generated from the power device 150 to thereby minimize the heat generated from the power device 150 affecting the control devices 170 and 180.

In addition, the power module package 500 may further include second vias 330 formed to penetrate from one surface of the second substrate 310 to the other surface thereof.

Here, the second via 330 may be connected to the metal plate 400.

The second via 330 is connected to the metal plate 400 to thereby allow the heat generated from the power device 150 to be more efficiently radiated.

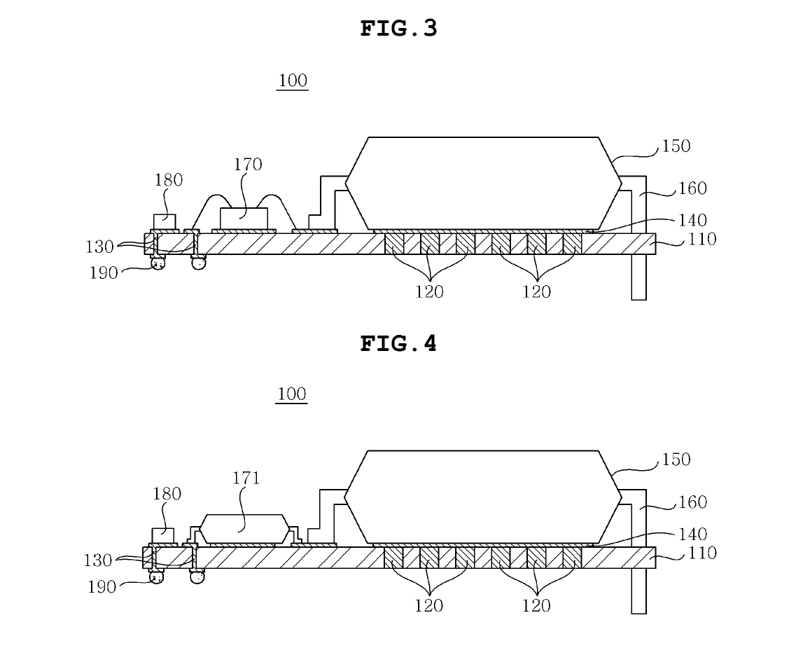

Meanwhile, as shown in FIGS. 3 and 4, the power module package 100 on the first substrate side is in a state in which the metal layer 140 is formed on the first substrate 110 having the first vias 120 and 130 thereon, the semiconductor devices 150, 170, and 180 are mounted on the metal layer 140, and then the wires or the lead frames for electrical connection therebetween are formed, before the second substrate 310 is coupled thereto.

In this case, the power module package 100 on the first substrate side will be defined as the power module package before being coupled to the second substrate 310 corresponding to a main board.

In addition, as the semiconductor devices 150, 170, and 180, package type of devices 150 and 170 as well as bare devices may also be applied.

The bare device means a device not included in a package and cut from a wafer, and the package type of device means a device included in a package.

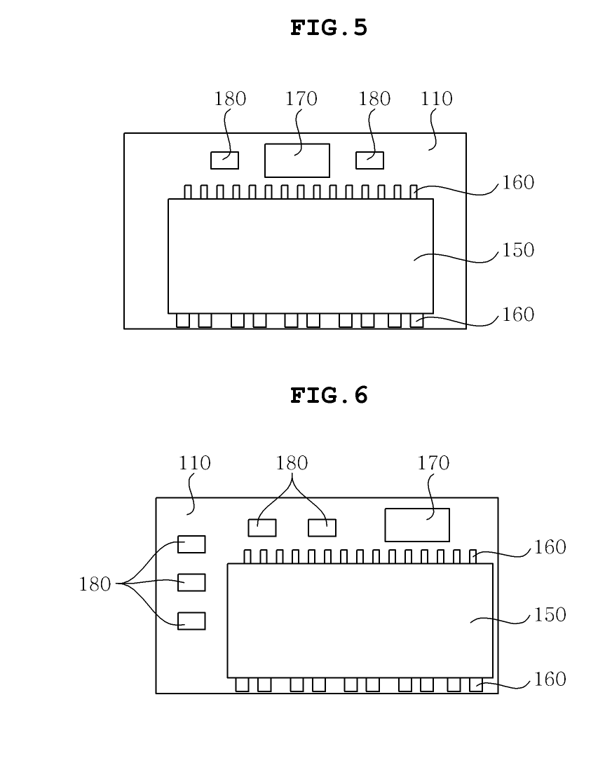

In the embodiment of the present invention, the first substrate 110 primarily functions as an integrated board. That is, as shown in FIGS. 5 and 6, the first substrate 110 has the power device 150 and the control device 170 and 180 mounted thereon, thereby making it possible to improve degree of freedom in designs such as semiconductor device arrangement, circuit formation, or the like.

### Power Module Package—Second Preferred Embodiment

FIG. 2 is a cross-sectional view showing a configuration of a power module package according to a second preferred embodiment of the present invention, where a case the metal plate 400 is not included will be described.

Descriptions on the configuration of the second preferred embodiment overlapped with that of the first preferred embodiment will be omitted and only the different portions therebetween will be described.

As shown in FIG. 2, a power module package 500 may configured to include a first substrate 110 having one surface and the other surface, vias 120 and 130 formed to penetrate from one surface of the first substrate 110 to the other surface thereof, a metal layer 140 formed on one surface of the first substrate 110, and semiconductor devices 150, 170, and 180 formed on the metal layer 140.

Here, the semiconductor device may include a power device 150 and control devices 170 and 180.

In this configuration, the power device 150 and the control device 180 may also each be formed as a package type, as shown in FIGS. 1, 3 and 4.

For example, it will be defined that the power device 150 refers to a device having a large heat generation amount such as an insulated gate bipolar transistor (IGBT), diode, or the like, and the control devices 170 and 180 refer to a device having a smaller heat generation amount than the power device, such as a control integrated circuit (IC), a passive device, or the like.

In addition, the via may include a heat radiation via 120 and a signal via 130

Furthermore, a heat sink 200 may be formed on the power device 150.

In this configuration, the power device 150 having a larger heat generation amount than the control devices 170 and 180 is connected to the heat sink 200 and the heat radiation via 120, such that heat generated from the power device 150 can be effectively radiated.

In addition, due to effective heat radiation of the power device 150, operational reliability of the entire power module package 500 including the control devices 170 and 180 can also be improved.

In addition, the power device 150 may be formed on the metal layer 140 and be formed to correspond to a region on which the heat radiation vias 120 are formed

In addition, the power module package 500 may further include a second substrate 310 formed on the other surface of the first substrate 110.

In addition, the control devices 170 and 180 may be formed on the metal layer 140 and be formed to correspond to a region on which the signal vias 130 are formed.

In other words, as shown in FIG. 1, the control device 180 formed on the metal layer 140 is connected to an external connection terminal 190 through the signal vias 130 to thereby be connected to the second substrate 310.

FIG. 1 shows a case in which the first substrate 110 and the second substrate 310 are connected to each other in a ball grid array (BGA) scheme, but the present invention is not limited thereto and the first substrate 110 and the second substrate 310 may also be connected to each other in a land grid array (LGA) scheme, or the like.

As shown in FIGS. 1, 3 and 4, in the case of a package type of the semiconductor devices, the power module package 500 may further include a lead frame 160 electrically interconnecting the package type of semiconductor devices and the metal layer.

As shown in FIG. 1, the power module package 500 may further include a wire electrically interconnecting the semiconductor device 170 and the metal layer 140

In the embodiment of the present invention, the first substrate 110 primarily functions as an integrated board. That is, as shown in FIGS. 5 and 6, the first substrate 110 has the power device 150 and the control devices 170 and 180 mounted thereon, thereby making it possible to improve degree of freedom in designs such as a semiconductor device arrangement, circuit formation, or the like.

With the power module package according to the preferred embodiment of the present invention, the power device having high radiation characteristics and the control devices are separately disposed to minimize influence of heat generated from the power device on the control devices which are relatively thermally weak, thereby making it possible to improve reliability of the module and performance thereof.

With the power module package according to the preferred embodiment of the present invention, the heat radiation via and the heat sink are connected to the power device and the heat radiation via is formed on the substrate corresponding to a main board, thereby making it possible to maximize heat radiation effect.

According to the preferred embodiment of the present invention, the integrated substrate having the semiconductor devices mounted thereon is separately formed to facilitate the disposition and addition of the semiconductor devices according to usage of the module and the specification thereof, thereby making it possible to improve the degree of freedom in designing the entire power module package.

In addition, according to the preferred embodiment of the present invention, the power device and control devices are each separately implemented, whereby the change in design of the entire module according to the usage of the module may be facilitated to improve productivity and waste thereof at the time of occurrence of defects may also be reduced.

Although the embodiment of the present invention has been disclosed for illustrative purposes, it will be appreciated that a power module package according to the invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A power module package, comprising:
a first substrate having one surface and the other surface;
first vias formed to penetrate from one surface of the first substrate to the other surface thereof;
a metal layer formed on one surface of the first substrate;
semiconductor devices formed on the metal layer; and
a metal plate formed on the other surface of the first substrate.

2. The power module package as set forth in claim 1, further comprising a heat sink formed on a power device, wherein the semiconductor devices include the power device and control devices.

3. The power module package as set forth in claim 1, wherein the semiconductor devices include a power device and control devices, and the first vias include a heat radiation via and a signal via, the power device being formed on the metal layer and being formed to correspond to a region on which the heat radiation via is formed.

4. The power module package as set forth in claim 1, wherein the first vias include a heat radiation via and a signal via, and the metal plate is connected to the heat radiation via.

5. The power module package as set forth in claim 1, wherein the semiconductor devices include a power device and control devices, and the first vias include a heat radiation via and a signal via, the control devices being formed on the metal layer and being formed to correspond to a region on which the signal via is formed.

6. The power module package as set forth in claim 1, wherein the semiconductor devices include a power device and control devices, the power device and the control devices each being formed as a package type.

7. The power module package as set forth in claim 1, further comprising a lead frame electrically interconnecting a package type of semiconductor device and the metal layer, in the case of the package type of semiconductor device.

8. The power module package as set forth in claim 1, further comprising a wire electrically interconnecting the semiconductor device and the metal layer.

9. The power module package as set forth in claim 1, further comprising a second substrate formed on the other surface of the first substrate and connected to the first substrate through the metal plate.

10. The power module package as set forth in claim 9, further comprising second vias formed to penetrate from one surface of the second substrate to the other surface thereof,
wherein the second via is connected to the metal plate.

11. A power module package, comprising:
a first substrate having one surface and the other surface;
vias formed to penetrate from one surface of the first substrate to the other surface thereof;
a metal layer formed on one surface of the first substrate; and
semiconductor devices formed on the metal layer.

12. The power module package as set forth in claim 11, further comprising a heat sink formed on a power device, wherein the semiconductor devices include the power device and control devices.

13. The power module package as set forth in claim 11, wherein the semiconductor devices include a power device and control devices, and the vias include a heat radiation via and a signal via, the power device being formed on the metal layer and being formed to correspond to a region on which the heat radiation via is formed.

14. The power module package as set forth in claim 11, wherein the semiconductor devices include a power device and control devices, and the vias include a heat radiation via and a signal via, the control devices being formed on the metal layer and being formed to correspond to a region on which the signal via is formed.

15. The power module package as set forth in claim 11, wherein the semiconductor devices include a power device and control devices, the power device and the control devices each being formed as a package type.

16. The power module package as set forth in claim 11, further comprising a lead frame electrically interconnecting a package type of semiconductor device and the metal layer, in the case of the package type of semiconductor device.

17. The power module package as set forth in claim 11, further comprising a wire electrically interconnecting the semiconductor device and the metal layer.

18. The power module package as set forth in claim 11, further comprising a second substrate formed on the other surface of the first substrate.
